(19) United States
(12) Patent Application Publication
(10) Pub. No.: US 2026/0127351 A1
(43) Pub. Date: May 7, 2026

(54) SIMULATION MODEL STABILITY DETERMINATION METHOD

(71) Applicant: ASML NETHERLANDS B.V., Veldhoven (NL)

(72) Inventors: Jiaxing REN, Sunnyvale, CA (US); Yi-Yin CHEN, Santa Clara, CA (US); Yongfa FAN, Cupertino, CA (US); Jiao LIANG, San Jose, CA (US)

(73) Assignee: ASML NETHERLANDS B.V., Veldhoven (NL)

(21) Appl. No.: 18/704,308

(22) PCT Filed: Oct. 24, 2022
(86) PCT No.: PCT/EP2022/079676

§ 371 Date: Apr. 24, 2024

Related U.S. Application Data
(60) Provisional application No. 63/281,228, filed on Nov. 19, 2021.

(51) Int. Cl. G06F 30/398; G03F 7/00

(52) U.S. Cl. CPC G06F 30/398; G03F 7/70441; G03F 7/705; G03F 7/70625

(57) ABSTRACT

A grid dependency check for a simulation model is described. According to embodiments, a grid dependency check can be advantageously performed faster and more efficiently compared to prior grid dependency checks. Certain portions of a design layout are selected and cropped to a minimum size required by the model, and used to generate a second design layout. The selected portions are rotated and/or shifted relative to the grid to form one or more moved portions. The second design layout includes the one or more selected portions and the one or more moved portions so that a modeling operation (e.g., model apply) needs to only run a single time instead of multiple times as in prior grid dependency checks.

### CROSS-REFERENCE TO RELATED APPLICATIONS

This application claims priority of U.S. application 63/281,228 which was filed on Nov. 19, 2021 and which is incorporated herein in its entirety by reference.

### TECHNICAL FIELD

The present disclosure relates generally to determining simulation model stability associated with computational lithography.

### BACKGROUND

A lithographic projection apparatus can be used, for example, in the manufacture of integrated circuits (ICs). A patterning device (e.g., a mask) may include or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate contains a plurality of adjacent target portions to which the pattern is transferred successively by the lithographic projection apparatus, one target portion at a time. In one type of lithographic projection apparatus, the pattern on the entire patterning device is transferred onto one target portion in one operation. Such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic projection apparatus will have a reduction ratio M (e.g., 4), the speed F at which the substrate is moved will be 1/M times that at which the projection beam scans the patterning device. More information with regard to lithographic devices can be found in, for example, U.S. Pat. No. 6,046,792, incorporated herein by reference.

Prior to transferring the pattern from the patterning device to the substrate, the substrate may undergo various procedures, such as priming, resist coating and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish the individual layer of the device. If several layers are required in the device, then the whole procedure, or a variant thereof, is repeated for each layer. Eventually, a device will be present in each target portion on the substrate. These devices are then separated from one another by a technique such as dicing or sawing, such that the individual devices can be mounted on a carrier, connected to pins, etc.

Manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc.

Lithography is a central step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced. At the same time, the number of functional elements, such as transistors, per device has been steadily increasing, following a trend commonly referred to as “Moore's law.” At the current state of technology, layers of devices are manufactured using lithographic projection apparatuses that project a design layout onto a substrate using illumination from a deep-ultraviolet illumination source, creating individual functional elements having dimensions well below 100 nm, i.e. less than half the wavelength of the radiation from the illumination source (e.g., a 193 nm illumination source).

This process in which features with dimensions smaller than the classical resolution limit of a lithographic projection apparatus are printed, is commonly known as low-k1 lithography, according to the resolution formula CD=k1×λ/NA, where λ is the wavelength of radiation employed (currently in most cases 248 nm or 193 nm), NA is the numerical aperture of projection optics in the lithographic projection apparatus, CD is the “critical dimension”—generally the smallest feature size printed—and k1 is an empirical resolution factor. In general, the smaller k1 the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but not limited to, optimization of NA and optical coherence settings, customized illumination schemes, use of phase shifting patterning devices, optical proximity correction (OPC, sometimes also referred to as “optical and process correction”) in the design layout, source mask optimization (SMO), or other methods generally defined as “resolution enhancement techniques” (RET).

### SUMMARY

A grid dependency check for a simulation model is described. According to embodiments of the present disclosure, a grid dependency check can be advantageously performed faster and more efficiently compared to prior grid dependency checks. Certain portions of a design layout are selected and cropped to the minimum size required by the model, and used to generate a second design layout. The selected portions are rotated and/or shifted relative to the grid to form one or more moved portions. The second design layout includes the one or more selected portions and the one or more moved portions so that a modeling operation (e.g., model apply) needs to only run a single time instead of multiple times as in the prior grid dependency checks.

Thus, according to an embodiment, there is provided a non-transitory computer readable medium having instructions thereon. The instructions, when executed by one or more processors, cause the one or more processors to perform a method. The method comprises extracting one or more selected portions of a first pattern layout. The first pattern layout is overlaid on a grid. The method comprises moving the one or more selected portions relative to the grid to form one or more moved portions. The method generating a second pattern layout comprising the one or more selected portions and the one or more moved portions. The method comprises providing the second pattern layout to a simulation model to determine one or more predicted characteristics for the one or more selected portions and the one or more moved portions.

In some embodiments, the method further comprises determining a stability of the simulation model based on the one or more predicted characteristics.

In some embodiments, determining the stability comprises determining one or more predicted characteristics associated with the one or more selected portions and the one or more moved portions with the simulation model based on the second pattern layout.

In some embodiments, determining the stability of the simulation model based on the one or more predicted characteristics comprises a grid dependency (GD) check of the simulation model.

In some embodiments, a predicted characteristic comprises a predicted image and/or a predicted geometry for the second pattern layout.

In some embodiments, determining the one or more predicted characteristics comprises generating the predicted image. The predicted image comprises a resist image. The one or more predicted characteristics are derived from the predicted image.

In some embodiments, the predicted characteristic comprises the predicted geometry, and the predicted geometry comprises an etch contour.

In some embodiments, a predicted characteristic comprises a predicted critical dimension (CD) for the second pattern layout.

In some embodiments, the predicted characteristic comprises a plurality of critical dimensions predicted by the simulation model for the one or more selected portions and the one or more moved portions in the second pattern layout. Determining a stability of the simulation model is based on a range of the plurality of critical dimensions.

In some embodiments, moving the one or more selected portions relative to the grid comprises rotating and/or shifting the one or more selected portions relative to the grid.

In some embodiments, a size of the one or more selected portions is determined based on simulation model erosion.

In some embodiments, a size of the one or more selected portions is minimized based on simulation model erosion.

In some embodiments, a selected portion has a dimension of about 1 to about 20 micrometers.

In some embodiments, the pattern layout comprises a design layout for a semiconductor manufacturing process.

In some embodiments, the simulation model comprises a lithography simulation model.

In some embodiments, a selected portion has a first dimension for an extreme ultraviolet (EUV) semiconductor manufacturing process, or a second, larger dimension, for a deep ultraviolet (DUV) semiconductor manufacturing process.

In some embodiments, the simulation model is configured for an optical proximity correction (OPC) process. The one or more selected portions have a smaller dimensional size than portions used by the simulation model in the OPC process.

In some embodiments, the instructions further cause the one or more processors to electronically access the first pattern layout. The first pattern layout comprises a graphic design system (.GDS) or OASIS file.

According to another embodiment, there is provided a method for determining a stability of a simulation model. The method comprises one or more of the method steps described above.

According to another embodiment, there is provided a system for determining a stability of a simulation model. The system comprises one or more hardware processors configured by machine readable instructions to perform one or more of the method steps stated above.

### BRIEF DESCRIPTION OF THE DRAWINGS

The accompanying drawings, which are incorporated in and constitute a part of the specification, illustrate one or more embodiments and, together with the description, explain these embodiments. Embodiments of the invention will now be described, by way of example only, with reference to the accompanying schematic drawings in which corresponding reference symbols indicate corresponding parts, and in which:

FIG. 1 illustrates a block diagram of various subsystems of a lithographic projection apparatus, according to an embodiment of the present disclosure.

FIG. 2 illustrates a flow chart of an exemplary method for simulating lithography in a lithographic projection apparatus, according to an embodiment of the present disclosure.

FIG. 3 illustrates an exemplary method for determining a stability of a simulation model, according to an embodiment of the present disclosure.

FIG. 4 illustrates how model instability may be caused by a relative grid position of a portion of a pattern layout, according to an embodiment of the present disclosure.

FIG. 5 illustrates a process of shifting a selected portion of a design (pattern) layout several times, modelling the shifted selected portions, and determining corresponding critical dimensions for each shift, according to an embodiment of the present disclosure.

FIG. 6 illustrates generating a pattern layout comprising one or more selected portions and one or more moved portions of a pattern layout, according to an embodiment of the present disclosure.

FIG. 7 is a block diagram of an example computer system, according to an embodiment of the present disclosure.

FIG. 8 is a schematic diagram of a lithographic projection apparatus, according to an embodiment of the present disclosure.

FIG. 9 is a schematic diagram of another lithographic projection apparatus, according to an embodiment of the present disclosure.

FIG. 10 is a detailed view of a lithographic projection apparatus, according to an embodiment of the present disclosure.

FIG. 11 is a detailed view of a source collector module of the lithographic projection apparatus, according to an embodiment of the present disclosure

### DETAILED DESCRIPTION

In semiconductor manufacturing, for example, simulation model stability can be evaluated through grid dependency (GD) checks which can indicate a simulation model prediction's dependence on the positions of pattern features relative to an underlying grid in a design (pattern) layout. A simulation model prediction can change if the pattern layout shifts relative to the grid. Thus, grid dependency is typically monitored and controlled for simulation models associated with semiconductor manufacturing and/or other applications. For example, during model operation, a specified geometry may be overlaid on a mesh grid, then the model may be evaluated using the grid. Off-grid model values (e.g., for features that are not aligned with a portion of the grid) are obtained through interpolation. Noticeable interpolation errors may occur if the model is not properly configured. Such a model may be prone to a grid dependency error. Grid dependency causes model instability and accuracy degradation. A grid dependency check is configured to check and/or monitor the grid dependency and model stability.

According to embodiments of the present disclosure, certain portions of a design (pattern) layout are selected and cropped to the minimum size required by the model, and used to generate a second design layout. The selected portions are rotated and/or shifted relative to the grid to form one or more moved portions. The second design layout includes the one or more selected portions and the one or more moved portions so that a modeling operation (e.g., model apply) needs to only run a single time instead of multiple times as in the prior grid dependency checks.

Embodiments of the present disclosure are described in detail with reference to the drawings, which are provided as illustrative examples of the disclosure so as to enable those skilled in the art to practice the disclosure. Notably, the figures and examples below are not meant to limit the scope of the present disclosure to a single embodiment, but other embodiments are possible by way of interchange of some or all of the described or illustrated elements. Moreover, where certain elements of the present disclosure can be partially or fully implemented using known components, only those portions of such known components that are necessary for an understanding of the present disclosure will be described, and detailed descriptions of other portions of such known components will be omitted so as not to obscure the disclosure. Embodiments described as being implemented in software should not be limited thereto, but can include embodiments implemented in hardware, or combinations of software and hardware, and vice-versa, as will be apparent to those skilled in the art, unless otherwise specified herein. In the present specification, an embodiment showing a singular component should not be considered limiting; rather, the disclosure is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present disclosure encompasses present and future known equivalents to the known components referred to herein by way of illustration.

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “projection optics,” as used herein, should be broadly interpreted as encompassing various types of optical systems, including refractive optics, reflective optics, apertures and catadioptric optics, for example. The term “projection optics” may also include components operating according to any of these design types for directing, shaping, or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the (e.g., semiconductor) patterning device, and/or optical components for shaping, adjusting and/or projecting the radiation after the radiation passes the patterning device. The projection optics generally exclude the source and the patterning device.

A (e.g., semiconductor) patterning device can comprise, or can form, one or more patterns. The pattern can be generated utilizing CAD (computer-aided design) programs, based on a pattern or design layout, this process often being referred to as EDA (electronic design automation). Most CAD programs follow a set of predetermined design rules in order to create functional design layouts/patterning devices. These rules are set by processing and design limitations. For example, design rules define the space tolerance between devices (such as gates, capacitors, etc.) or interconnect lines, so as to ensure that the devices or lines do not interact with one another in an undesirable way. The design rules may include and/or specify specific parameters, limits on and/or ranges for parameters, and/or other information. One or more of the design rule limitations and/or parameters may be referred to as a “critical dimension” (CD). A critical dimension of a device can be defined as the smallest width of a line or hole or the smallest space between two lines or two holes, or other features. Thus, the CD determines the overall size and density of the designed device. One of the goals in device fabrication is to faithfully reproduce the original design intent on the substrate (via the patterning device).

The term “mask” or “patterning device” as employed in this text may be broadly interpreted as referring to a generic semiconductor patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include a programmable mirror array and a programmable LCD array.

An example of a programmable mirror array can be a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic means. An example of a programmable LCD array is given in U.S. Pat. No. 5,229,872, which is incorporated herein by reference.

As used herein, the term “patterning process” generally means a process that creates an etched substrate by the application of specified patterns of light as part of a lithography process. However, “patterning process” can also include (e.g., plasma) etching, as many of the features described herein can provide benefits to forming printed patterns using etch (e.g., plasma) processing.

As used herein, the term “pattern” means an idealized pattern that is to be etched on a substrate (e.g., wafer)—e.g., based on the design layout described above. A pattern may comprise, for example, various shape(s), arrangement(s) of features, contour(s), etc.

As used herein, a “printed pattern” means the physical pattern on a substrate that was etched based on a target pattern. The printed pattern can include, for example, troughs, channels, depressions, edges, or other two and three dimensional features resulting from a lithography process.

As used herein, the term “prediction model”, “process model”, “electronic model”, and/or “simulation model” (which may be used interchangeably) means a model that includes one or more models that simulate a patterning process. For example, a model can include an optical model (e.g., that models a lens system/projection system used to deliver light in a lithography process and may include modelling the final optical image of light that goes onto a photoresist), a resist model (e.g., that models physical effects of the resist, such as chemical effects due to the light), an OPC model (e.g., that can be used to make target patterns and may include sub-resolution resist features (SRAFs), etc.), an etch (or etch bias) model (e.g., that simulates the physical effects of an etching process on a printed wafer pattern), a source mask optimization (SMO) model, and/or other models.

As used herein, the term “calibrating” means to modify (e.g., improve or tune) and/or validate a model, an algorithm, and/or other components of a present system and/or method.

A patterning system may be a system comprising any or all of the components described above, plus other components configured to performing any or all of the operations associated with these components. A patterning system may include a lithographic projection apparatus, a scanner, system is configured to apply and/or remove resist, etching systems, and/or other systems, for example.

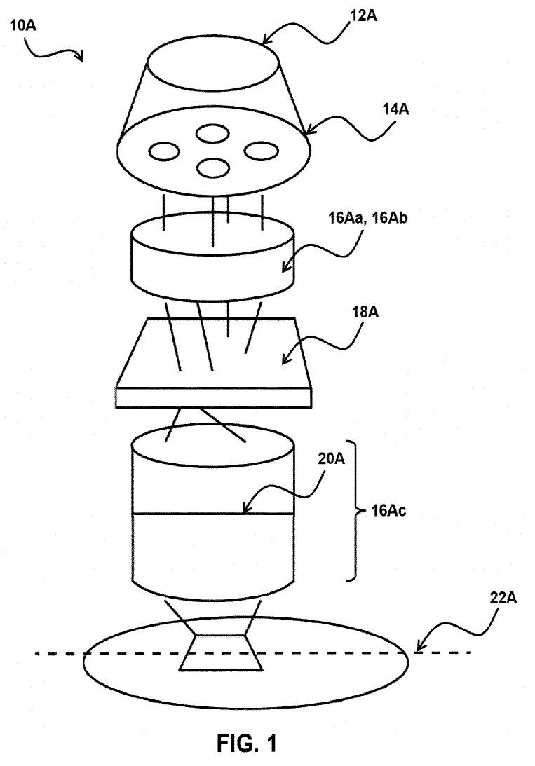

As an introduction, FIG. 1 illustrates a diagram of various subsystems of an example lithographic projection apparatus 10A. Major components are a radiation source 12A, which may be a deep-ultraviolet excimer laser source or other type of source including an extreme ultra violet (EUV) source (however, the lithographic projection apparatus itself need not have the radiation source), illumination optics which, for example, define the partial coherence (denoted as sigma) and which may include optics components 14A, 16Aa and 16Ab that shape radiation from the source 12A; a patterning device 18A; and transmission optics 16Ac that project an image of the patterning device pattern onto a substrate plane 22A. An adjustable filter or aperture 20A at the pupil plane of the projection optics may restrict the range of beam angles that impinge on the substrate plane 22A, where the largest possible angle defines the numerical aperture of the projection optics NA=n sin(Φₘₐₓ), wherein n is the refractive index of the media between the substrate and the last element of the projection optics, and Φₘₐₓ is the largest angle of the beam exiting from the projection optics that can still impinge on the substrate plane 22A.

In a lithographic projection apparatus, a source provides illumination (i.e. radiation) to a patterning device and projection optics direct and shape the illumination, via the patterning device, onto a substrate. The projection optics may include at least some of the components 14A, 16Aa, 16Ab and 16Ac. An aerial image (AI) is the radiation intensity distribution at substrate level. A resist model can be used to calculate the resist image from the aerial image, an example of which can be found in U.S. Patent Application Publication No. US 2009-0157630, the disclosure of which is hereby incorporated by reference in its entirety. The resist model is related to properties of the resist layer (e.g., effects of chemical processes which occur during exposure, post-exposure bake (PEB) and development). Optical properties of the lithographic projection apparatus (e.g., properties of the illumination, the patterning device, and the projection optics) dictate the aerial image and can be defined in an optical model. Since the patterning device used in the lithographic projection apparatus can be changed, it is desirable to separate the optical properties of the patterning device from the optical properties of the rest of the lithographic projection apparatus including at least the source and the projection optics. Details of techniques and models used to transform a design layout into various lithographic images (e.g., an aerial image, a resist image, etc.), apply OPC using those techniques and models and evaluate performance (e.g., in terms of process window) are described in U.S. Patent Application Publication Nos. US 2008-0301620, 2007-0050749, 2007-0031745, 2008-0309897, 2010-0162197, and 2010-0180251, the disclosure of each which is hereby incorporated by reference in its entirety.

It may be desirable to use one or more tools to produce results that, for example, can be used to design, control, monitor, etc. the patterning process. One or more tools used in computationally controlling, designing, etc. one or more aspects of the patterning process, such as the pattern design for a patterning device (including, for example, adding sub-resolution assist features or optical proximity corrections), the illumination for the patterning device, etc., may be provided. Accordingly, in a system for computationally controlling, designing, etc. a manufacturing process involving patterning, the manufacturing system components and/or processes can be described by various functional modules and/or models. In some embodiments, one or more electronic (e.g., mathematical, parameterized, machine learning, etc.) models may be provided that describe one or more steps and/or apparatuses of the patterning process. In some embodiments, a simulation of the patterning process can be performed using one or more electronic models to simulate how the patterning process forms a patterned substrate using a pattern provided by a patterning device.

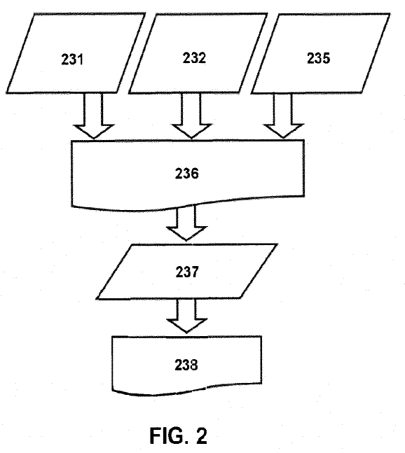

An exemplary flow chart for simulating lithography in a lithographic projection apparatus is illustrated in FIG. 2. An illumination model 231 represents optical characteristics (including radiation intensity distribution and/or phase distribution) of the illumination. A projection optics model 232 represents optical characteristics (including changes to the radiation intensity distribution and/or the phase distribution caused by the projection optics) of the projection optics. A design layout model 235 represents optical characteristics (including changes to the radiation intensity distribution and/or the phase distribution caused by a given design layout) of a design layout, which is the representation of an arrangement of features on or formed by a patterning device. An aerial image 236 can be simulated using the illumination model 231, the projection optics model 232, and the design layout model 235. A resist image 238 can be simulated from the aerial image 236 using a resist model 237. Simulation of lithography can, for example, predict contours and/or CDs in the resist image.

More specifically, illumination model 231 can represent the optical characteristics of the illumination that include, but are not limited to, NA-sigma (o) settings as well as any particular illumination shape (e.g. off-axis illumination such as annular, quadrupole, dipole, etc.). The projection optics model 232 can represent the optical characteristics of the of the projection optics, including, for example, aberration, distortion, a refractive index, a physical size or dimension, etc. The design layout model 235 can also represent one or more physical properties of a physical patterning device, as described, for example, in U.S. Pat. No. 7,587,704, which is incorporated by reference in its entirety. Optical properties associated with the lithographic projection apparatus (e.g., properties of the illumination, the patterning device, and the projection optics) dictate the aerial image. Since the patterning device used in the lithographic projection apparatus can be changed, it is desirable to separate the optical properties of the patterning device from the optical properties of the rest of the lithographic projection apparatus including at least the illumination and the projection optics (hence design layout model 235).

The resist model 237 can be used to calculate the resist image from the aerial image, an example of which can be found in U.S. Pat. No. 8,200,468, which is hereby incorporated by reference in its entirety. The resist model is typically related to properties of the resist layer (e.g., effects of chemical processes which occur during exposure, post-exposure bake and/or development).

One of the objectives of the full simulation is to accurately predict, for example, edge placements, aerial image intensity slopes and/or CDs, which can then be compared against an intended design. The intended design is generally defined as a pre-OPC design (or pattern) layout which can be provided in a standardized digital file format such as .GDS, .GDSII, .OASIS, or other file formats.

From the design (pattern) layout, one or more portions may be identified, which are referred to as “clips.” In an embodiment, a set of clips is extracted, which represents the complicated patterns in the design (pattern) layout (often hundreds or thousands of clips, although any number of clips may be used). As will be appreciated by those skilled in the art, these clips represent small portions (e.g., circuits, cells, etc.) of the design and may represent small portions for which particular attention and/or verification is needed. In other words, clips may be the portions of the design (pattern) layout or may be similar or have a similar behavior of portions of the design (pattern) layout where critical features are identified either by experience (including clips provided by a customer), by trial and error, or by running a full-chip simulation. Clips may contain one or more test patterns or gauge patterns. An initial larger set of clips may be provided a priori by a customer based on known critical feature areas in a design (pattern) layout which require particular image optimization. Alternatively, in another embodiment, the initial larger set of clips may be extracted from the entire design (pattern) layout by using an automated (such as, machine vision) or manual algorithm that identifies the critical feature areas.

Based on the clips (and/or other information), simulation and modeling can be used to configure one or more features of the patterning device pattern (e.g., performing optical proximity correction), one or more features of the illumination (e.g., changing one or more characteristics of a spatial/angular intensity distribution of the illumination, such as change a shape), and/or one or more features of the projection optics (e.g., numerical aperture, etc.). Such configuration can be generally referred to as, respectively, mask optimization, source optimization, and projection optimization.

Such optimization can be performed on their own, or combined in different combinations. One such example is source-mask optimization (SMO), which involves the configuring of one or more features of the patterning device pattern together with one or more features of the illumination. The optimization techniques may focus on one or more of the clips.

Similar modelling techniques may be applied for optimizing an etching process, for example, and/or other processes. In some embodiments, illumination model 231, projection optics model 232, design layout model 235, resist model 237, and/or other models may be used in conjunction with an etch model, for example. For example, output from an after development inspection (ADI) model (e.g., included as some and/or all of design layout model 235, resist model 237, and/or other models) may be used to determine an ADI contour, which may be provided to an effective etch bias (EEB) model to generate a predicted after etch inspection (AEI) contour.

In some embodiments, an optimization process of a system may be represented as a cost function. The optimization process may comprise finding a set of parameters (design variables, process variables, etc.) of the system that minimizes the cost function. The cost function can have any suitable form depending on the goal of the optimization. For example, the cost function can be weighted root mean square (RMS) of deviations of certain characteristics (evaluation points) of the system with respect to the intended values (e.g., ideal values) of these characteristics. The cost function can also be the maximum of these deviations (i.e., worst deviation). The term “evaluation points” should be interpreted broadly to include any characteristics of the system or fabrication method. The design and/or process variables of the system can be confined to finite ranges and/or be interdependent due to practicalities of implementations of the system and/or method. In the case of a lithographic projection apparatus, the constraints are often associated with physical properties and characteristics of the hardware such as tunable ranges, and/or patterning device manufacturability design rules. The evaluation points can include physical points on a resist image on a substrate, as well as non-physical characteristics such as one or more etching parameters, dose and focus, etc., for example.

In an etching system, as an example, a cost function (CF) may be expressed as

$$CF ( {z}_{1} , {z}_{2} , ⋯ , {z}_{N} ) = {\sum }_{p = 1}^{P} {w}_{p} {f}_{p}^{2} ( {z}_{1} , {z}_{2} , ⋯ , {z}_{N} )$$

where (z₁, z₂, . . . , z_{N}) are N design variables or values thereof, and fₚ(z₁, z₂, . . . , z_{N}) can be a function of the design variables (z₁, z₂, . . . , z_{N}) such as a difference between an actual value and an intended value of a characteristic for a set of values of the design variables of (z₁, z₂, . . . , z_{N}). In some embodiments, wₚ is a weight constant associated with fₚ(z₁, z₂, . . . , z_{N}). For example, the characteristic may be a position of an edge of a pattern, measured at a given point on the edge. Different fₚ(z₁, z₂, . . . , z_{N}) may have different weight wₚ. For example, if a particular edge has a narrow range of permitted positions, the weight wₚ for the fₚ(z₁, z₂, . . . , z_{N}) representing the difference between the actual position and the intended position of the edge may be given a higher value. fₚ(z₁, z₂, . . . , z_{N}) can also be a function of an interlayer characteristic, which is in turn a function of the design variables (z₁, z₂, . . . , z_{N}). Of course, CF(z₁, z₂, . . . , z_{N}) is not limited to the form in the equation above and CF(z₁, z₂, . . . , z_{N}) can be in any other suitable form.

The cost function may represent any one or more suitable characteristics of the etching system, etching process, lithographic apparatus, lithography process, or the substrate, for instance, focus, CD, image shift, image distortion, image rotation, stochastic variation, throughput, local CD variation, process window, an interlayer characteristic, or a combination thereof. In some embodiments, the cost function may include a function that represents one or more characteristics of a resist image. For example, fₚ(z₁, z₂, . . . , z_{N}) can be simply a distance between a point in the resist image to an intended position of that point (i.e., edge placement error EPEₚ(z₁, z₂, . . . , z_{N}) after etching, for example, and/or some other process. The parameters (e.g., design variables) can include any adjustable parameter such as an adjustable parameter of the etching system, the source, the patterning device, the projection optics, dose, focus, etc.

The parameters (e.g., design variables) may have constraints, which can be expressed as (z₁, z₂, . . . , z_{N})∈Z, where Z is a set of possible values of the design variables. One possible constraint on the design variables may be imposed by a desired throughput of the lithographic projection apparatus. Without such a constraint imposed by the desired throughput, the optimization may yield a set of values of the design variables that are unrealistic. Constraints should not be interpreted as a necessity.

In some embodiments, illumination model 231, projection optics model 232, design layout model 235, resist model 237, an etch model, and/or other models associated with and/or included in an integrated circuit manufacturing process may be an empirical and/or other simulation model. The empirical model may predict outputs based on correlations between various inputs (e.g., one or more characteristics of a pattern, one or more characteristics of the patterning device, one or more characteristics of the illumination used in the lithographic process such as the wavelength, etc.).

As an example, the empirical model may be a machine learning model and/or any other parameterized model. In some embodiments, the machine learning model (for example) may be and/or include mathematical equations, algorithms, plots, charts, networks (e.g., neural networks), and/or other tools and machine learning model components. For example, the machine learning model may be and/or include one or more neural networks having an input layer, an output layer, and one or more intermediate or hidden layers. In some embodiments, the one or more neural networks may be and/or include deep neural networks (e.g., neural networks that have one or more intermediate or hidden layers between the input and output layers).

As an example, the one or more neural networks may be based on a large collection of neural units (or artificial neurons). The one or more neural networks may loosely mimic the manner in which a biological brain works (e.g., via large clusters of biological neurons connected by axons). Each neural unit of a neural network may be connected with many other neural units of the neural network. Such connections can be enforcing or inhibitory in their effect on the activation state of connected neural units. In some embodiments, each individual neural unit may have a summation function that combines the values of all its inputs together. In some embodiments, each connection (or the neural unit itself) may have a threshold function such that a signal must surpass the threshold before it is allowed to propagate to other neural units. These neural network systems may be self-learning and trained, rather than explicitly programmed, and can perform significantly better in certain areas of problem solving, as compared to traditional computer programs. In some embodiments, the one or more neural networks may include multiple layers (e.g., where a signal path traverses from front layers to back layers). In some embodiments, back propagation techniques may be utilized by the neural networks, where forward stimulation is used to reset weights on the “front” neural units. In some embodiments, stimulation and inhibition for the one or more neural networks may be freer flowing, with connections interacting in a more chaotic and complex fashion. In some embodiments, the intermediate layers of the one or more neural networks include one or more convolutional layers, one or more recurrent layers, and/or other layers.

The one or more neural networks may be trained (i.e., whose parameters are determined) using a set of training information. The training information may include a set of training samples. Each sample may be a pair comprising an input object (typically a vector, which may be called a feature vector) and a desired output value (also called the supervisory signal). A training algorithm analyzes the training information and adjusts the behavior of the neural network by adjusting the parameters (e.g., weights of one or more layers) of the neural network based on the training information. For example, given a set of N training samples of the form {(x₁,y₁),(x₂,y₂), . . . ,(x_{N},y_{N})} such that xᵢ is the feature vector of the i-th example and yᵢ is its supervisory signal, a training algorithm seeks a neural network g: X→Y, where X is the input space and Y is the output space. A feature vector is an n-dimensional vector of numerical features that represent some object (e.g., a simulated aerial image, a wafer design, a clip, etc.). The vector space associated with these vectors is often called the feature space. After training, the neural network may be used for making predictions using new samples.

As another example, the empirical (simulation) model may comprise one or more algorithms. The one or more algorithms may be and/or include mathematical equations, plots, charts, and/or other tools and model components.

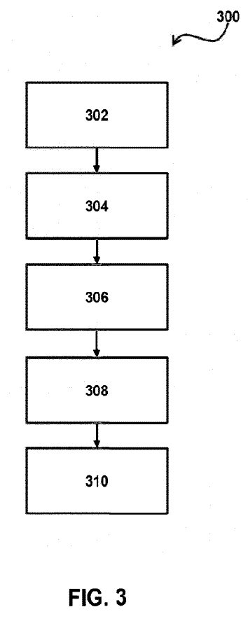

FIG. 3 illustrates an exemplary method 300 of determining a stability of a simulation model, according to an embodiment of the present disclosure. The stability of a simulation model refers to the consistency of simulation model predictions and/or other outputs, given the same or similar inputs. In some embodiments, the simulation model comprises a lithography simulation model for a semiconductor manufacturing process, and simulation model outputs comprise predicted contours, images, and/or other information, for example. In some embodiments, the simulation model is configured and used for an optical proximity correction (OPC) process, for example. In some embodiments, method 300 comprises a grid dependency check for the simulation model. The simulation model may be or include any of the models described above related to FIG. 2, and/or other models.

Grid dependency checking typically includes repeatedly (1) shifting a selected portion of a design (pattern) layout (e.g., a polygon and its gauges) by a certain amount (e.g., a subpixel distance, for instance 0.1 pixel) relative to a grid associated with the design layout, and (2) applying a simulation model to the selected portion for each shift to predict a critical dimension, until a full-pixel shift is covered. The selected portion may be a clip or patch including the polygon and its gauges, for example. Each shift results in a critical dimension prediction. The range of all of the predicted critical dimensions is used as a grid dependency metric. That is, the model is applied on each shifted version of the patch separately. A typical grid dependency check for a simulation model is very slow because the modelling process is repeated for each of several pattern shifts. The size of each shifted portion is also typically much larger (e.g., with an edge dimension of greater than about 20 micrometers) than that required for accurate grid dependency calculation, which wastes computing resources during each repeated modelling step. A typical grid dependency check uses the same patch size the regular model application uses (the regular model application is typically not for a grid dependency check). The regular model application needs to cover large areas or even entire chip layouts, and therefore uses a larger patch size to reduce the number of patches and the wasted area due to model erosion. In contrast, a grid dependency check only focuses on small areas around gauges.

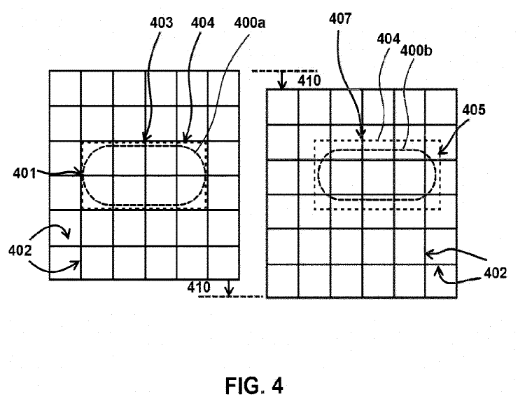

By way of a non-limiting example, FIG. 4 illustrates model instability that may be caused by a change in the relative grid shift of a selected portion of a pattern layout. Simulation model predictions 400a and 400b are determined based at least in part on the intersections 401, 403, 405, 407 (as several examples) of grid lines 402 with 404 an input polygon (for an ADI model), a contour (used in an AEI model), or other features of a pattern layout. When the position of the grid lines 402 relative to polygon/contour 404 changes, the prediction changes from prediction 400a to prediction 400b (and CD changes with the shifted input).

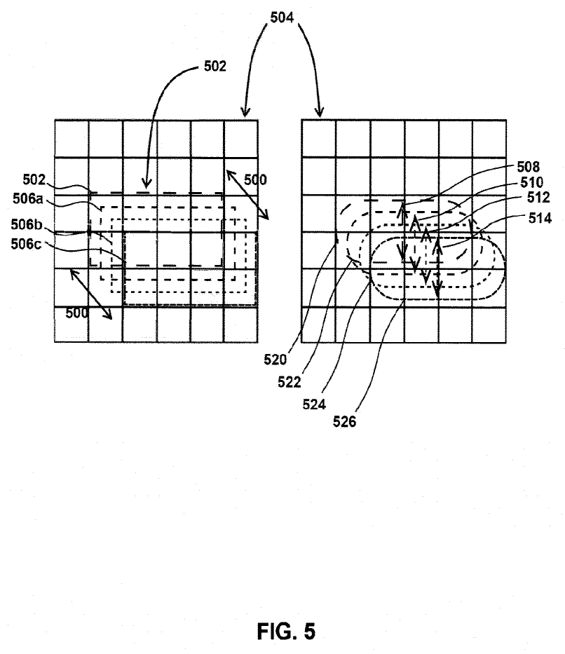

FIG. 5 illustrates a typical process of shifting 500 a selected portion 502 of a design (pattern) layout relative to a grid 504 by various amounts to create shifted selected portions 506a, 506b, and 506c, modelling selected portion 502 and the shifted selected portions 506a-506c, and determining corresponding critical dimensions 508, 510, 512, and 514 of each simulation model prediction 520, 522, 524, and 526 for selected portion 502 and each shifted selected portion 506a-506c. The range of these critical dimensions 508-514 may be indicative of a grid dependency of the simulation model and/or other simulation model stability, for example. As described above, grid dependency checking typically includes repeatedly (1) shifting selected portion 502 of a design (pattern) layout (e.g., a polygon in this example) by a certain amount (e.g., a subpixel distance for each shift until the shifting translates across a full grid 504 square (e.g., a full pixel shift) in this example) relative to grid 504 associated with the design layout, and (2) applying the simulation model to the selected portion for each shift to predict critical dimensions 508-514, until a full-pixel shift is covered. The range (e.g., maximum-minimum) of critical dimensions output by the simulation model for each shift is a grid dependency metric. Although embodiments discussed herein use CD range as a metric, the present disclosure is not limited thereto. Other metrics such as variance, standard deviation, etc., are contemplated.

Returning to FIG. 3, compared to prior model stability determinations and/or grid dependency checks, method 300 is performed faster and more efficiently compared to prior grid dependency checks. Certain portions of a design layout are selected and cropped to the minimum size required by the model, and used to generate a second design layout. The selected portions are rotated and/or shifted relative to the grid to form one or more moved portions. The second design layout includes the one or more selected portions and the one or more moved portions so that a modeling operation (e.g., model apply) needs to only run a single time instead of multiple times as in the prior grid dependency checks. The selected portions are rotated and/or shifted relative to the grid to form one or more moved portions. The one or more selected portions and the one or more moved portions are compiled into one design layout (the second design layout). The compiled design layout can be provided to the simulation model and a modeling operation need only run a single time to generate the predictions for all the input patterns and their shifted versions, as opposed to multiple times as in the prior grid dependency checks.

In some embodiments, method 300 comprises extracting 302 one or more selected portions of a first pattern layout, moving 304 the one or more selected portions relative to the grid to form one or more moved portions, generating 306 a second pattern layout comprising the one or more selected portions and the one or more moved portions, providing 308 the second pattern layout to a simulation model to determine one or more predicted characteristics for the one or more selected portions and the one or more moved portions, and determining 310 the stability of the simulation model based on the one or more predicted characteristics.

In some embodiments, a non-transitory computer readable medium stores instructions which, when executed by a computer, cause the computer to execute one or more of operations 302-310, and/or other operations. The operations of method 300 are intended to be illustrative. In some embodiments, method 300 may be accomplished with one or more additional operations not described, and/or without one or more of the operations discussed. For example, operation 310 and/or other operations may be optional. Additionally, the order in which the operations of method 300 are illustrated in FIG. 3 and described herein is not intended to be limiting.

At an operation 302, one or more selected portions of a (e.g., first) design (pattern) layout are extracted. In some embodiments, the one or more selected portions may be selected based on pattern polygons obtained directly from a pattern layout. In some embodiments, the one or more selected portions may be selected based on pattern images or contours of the pattern layout, where the images or contours can be obtained from any suitable inspection or metrology system, or simulation. For example, the selection may be based on aerial images, optical images, mask images, resist images, etch images, and/or wafer images of the patterns as measured or simulated. In some embodiments, the selected portions include all or a portion of gauges. The gauges are typically selected based on their geometry to have a good coverage of different pattern types.

In some embodiments, the (first) pattern layout comprises a design layout for a semiconductor manufacturing process. The (first) pattern layout may include one or more patterns. The patterns in a pattern layout may include two and/or three dimensional geometrical shapes, for example. This may include data that describes the characteristics of the shapes (e.g., such as X-Y dimensional data points, a mathematical equation that describes the geometrical shape, etc.), processing parameters associated with the shapes, and/or other data.

The pattern layout may comprise a simulation, an image, and electronic file, and/or other representations. The pattern layout may include information describing patterns of the pattern layout themselves and/or information related to the patterns. The patterns may include the geometrical shapes of contours in the pattern layout and/or information related to the geometrical shapes. Using a semiconductor chip as an example, a pattern layout may include one or more of the patterns that make up a chip design (e.g., including pattern layout structures configured to facilitate inspections and/or other operations). This may include channels, protrusions, vias, gratings, etc., as shown in a simulation, an image, a .GDS file, etc. For example, the first pattern layout may comprise a graphic design system (.GDS), OASIS file, and/or another design layout file.

In some embodiments, operation 302 comprises electronically accessing the first pattern layout, and extracting the one or more selected portions from the first pattern layout file. In some embodiments, the pattern layout comprises a .GDS file, a .GDSII file, a .OASIS file, and/or an electronic file having other file formats, and/or another electronic representation of the pattern layout. The pattern layout may be received electronically from one or more other portions of the present system (e.g., from a different processor, or from a different portion of a single processor), from a remote computing system not associated with a present system, and/or from other sources. The pattern layout may be received wirelessly and/or via wires, via a portable storage medium, and/or from other sources. The pattern layout may be uploaded and/or downloaded from another source, such as cloud storage for example, and/or received in other ways.

In some embodiments, a selected portion comprises a clip or patch that includes a polygon and corresponding gauges, for example. Extraction comprises cutting, taking out, or otherwise copying the selected portions of the first design (pattern) layout from the layout file (e.g., from the GDS file, the .GDSII file, the .OASIS file, etc.). This may be performed by a user with a computing device electronically selecting or copying the selected portions, for example.

In some embodiments, a size of the one or more selected portions is determined based on simulation model erosion. Model erosion for a particular model is the ambit or range within which the pattern has an impact on an evaluation point (e.g., in the center). For a given patch size, the patch will be eroded by the model erosion from each edge to determine the area where accurate simulation results can be obtained. Therefore, when the patch size/selected portion is larger than about two times the model erosion, the simulation result at the center of the patch can be accurately determined. Further increasing the patch size will not improve the simulation accuracy in the center. For the present simulation model stability check, since we only need to accurately determine a property at a gauge, we can minimize the patch size to be close to two times the model erosion.

In some embodiments, a size of the one or more selected portions is determined based on simulation model erosion. Determining the size of the one or more selected portions comprises determining the smallest size of a selected portion that, when moved, and provided to a simulation model as part of a second design (pattern) layout (as described below), still causes the simulation model to produce predictions for model stability evaluation purposes. Determining the size of the one or more selected portions reduces computing resources required by the simulation model, while still producing an accurate result. In some embodiments, the two times model erosion is used to determine the size of the cropped area such that accurate CD results are produced in the center. In some embodiments, the size of the cropped area can be further reduced to below two times model erosion. In such cases, the absolute CD value is no longer accurate but the grid dependency value can still be valid because it measures relative CD. Reducing the size can provide further speed improvement and/or have other advantages.

In some embodiments, a selected portion has a certain dimension for a simulation model configured for an extreme ultraviolet (EUV) semiconductor manufacturing process. In some embodiments, a selected portion has a different dimension for a simulation model configured for a deep ultraviolet (DUV) semiconductor manufacturing process. For example, in some embodiments, a selected portion has a dimension of about 3 micrometers for an extreme ultraviolet (EUV) semiconductor manufacturing process, or a dimension of about 7 micrometers for a deep ultraviolet (DUV) semiconductor manufacturing process. In some embodiments, as described above, the simulation model is used or applied in an optical proximity correction (OPC) process, and the one or more selected portions have a smaller dimensional size (e.g., an edge dimension of less than or equal to about 20 micrometers) than portions used by the simulation model in the OPC process (e.g., an edge dimension greater than about 20 micrometers).

At an operation 304, the one or more selected portions are moved relative to a grid to form one or more moved portions. For example, the (first) pattern layout is overlaid on a grid. The grid is determined by the particular application and model, and is not inherent to a pattern layout (e.g., a .GDS file). For the same pattern layout, the grid size and an origin point can be different depending on the model. The grid is determined when loading the model and pattern layout. The grid comprises a series of vertical an horizonal lines arranged so they intersect, though other grid configurations are possible. The grid provides a background reference or graphical framework for a pattern layout, for example.

Moving the one or more selected portions relative to the grid comprises rotating, shifting, and/or other movements of the one or more selected portions relative to the grid. Rotation comprises moving (revolving, spinning, etc.) features of a pattern or a portion of a pattern in the one or more selected portions around an axis of rotation in a two dimensional plane relative to the grid, for example. Shifting comprises translating the features of the pattern or the portion of the pattern in the one or more selected portions in an x and/or y direction (e.g., in the two dimensional plane) relative to the grid and/or any other non-rotational movement relative to the grid. In some embodiments, moving the one or more selected portions relative to the grid comprises moving graphical (e.g., x, y) coordinates of polygons and/or gauges of a selected portion relative to the grid. This may include mathematical rotations, shifts, translations, and/or other operations performed on such coordinates, for example. Any number of moved portions may be formed.

In some embodiments a movement comprises an incremental amount of sub-pixel shift against the grid. For example, a selected portion may include a polygon and its gauges. Moving the selected portion may include rotating and/or shifting (e.g., rotating, translating in an x and/or y direction, or both) the polygon and its gauges by a certain sub pixel amount (e.g., 0.1 pixel) relative to a grid.

In some embodiments, the same selected portion may be moved several times so that several moved portions are formed from the same selected portion. This may include rotating and/or shifting the selected portion incrementally several times to form the several moved portions. For example, a single portion of the pattern layout may be selected, extracted, and then copied several times. Each of the copies may be incrementally rotated and/or shifted as described. The selecting, extracting, and incremental rotating and/or shifting may be similarly repeated for other selected portions.

At an operation 306, another (e.g., a second) pattern layout comprising the one or more selected portions and the one or more moved portions is generated. Operation 306 comprises integrating all of the extracted selected portions and their moved portions into a composite (e.g., second) pattern layout. This composite second pattern layout may be a second .GDS, .GDSII, or .OASIS file, for example. The composite second pattern layout may be arranged in rows and/or columns, for example, and/or have other layouts. In this example, a row may be formed by a selected portion and its corresponding incrementally moved portions, with columns formed by other selected portions and their corresponding incrementally moved portions.

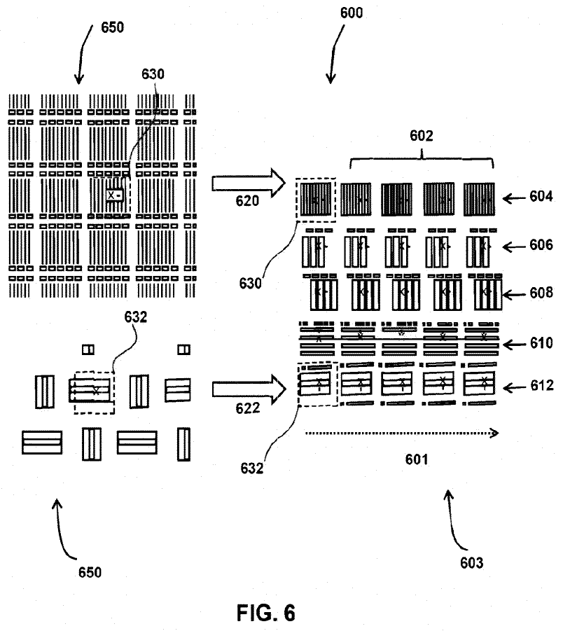

For example, FIG. 6 illustrates generating another (e.g., the second) pattern layout 603 comprising one or more selected portions 600 and one or more moved portions 602 of a first pattern layout 650. In the example shown in FIG. 6, the one or more selected portions 600 and one or more moved portions 602 are for different gauges 604, 606, 608, 610, and 612 of an area around a gauge-area 650 around gauge 604 as one example. Note that only two gauges 604 and 612 are explicitly shown as being extracted 620 and 622 (respectively) from pattern layout 650, though the others are similarly extracted. As shown in FIG. 6, a selected portion 600 (e.g., for gauges 604, 606, 608, 610, and 612) may be moved several times so that several moved portions 602 are formed from the same selected portion 600. This may include rotating and/or shifting the selected portion 600 incrementally 601 several times to form the several moved portions 602. For example, a single portion 630 or 632 of pattern layout 650 may be selected, extracted 620 or 622, and then copied several times. Each of the copies may be incrementally rotated and/or shifted as described (e.g., see moved portions 602 for each of portion 630 or 632). The selecting, extracting, and incremental rotating and/or shifting may be similarly repeated for other selected portions for gauges 606, 608, and 610, for example. All of the extracted selected portions 600 and their moved portions 602 are integrated into a composite (e.g., the second) pattern layout 603. This composite second pattern layout 603 may be a second .GDS, .GDSII, or .OASIS file, for example. The composite second pattern layout 603 may be arranged in rows and/or columns, as shown in FIG. 6 for example, and/or have other layouts.

Returning to FIG. 3, at an operation 308, the second pattern layout is provided to a simulation model. The second pattern layout is provided to the simulation model to determine one or more predicted characteristics for the one or more selected portions and the one or more moved portions. In some embodiments, as described above, the simulation model comprises a lithography simulation model for a semiconductor manufacturing process. The second pattern layout need only be provided for a model apply operation a single time, instead of multiple times corresponding to each pattern shift as in prior grid dependency checks.

The one or more predicted characteristics are determined based on the second pattern layout and/or other information. In some embodiments, a predicted characteristic comprises a predicted image, a predicted geometry, a predicted critical dimension (CD), a predicted edge placement error (EPE), a predicted edge placement (EP) and/or other information for the second pattern layout (e.g., the pattern layout comprising the one or more selected portions and the one or more moved portions). In some embodiments, determining the one or more predicted characteristics comprises generating a predicted image. The predicted image may comprise a resist image, for example, and the one or more predicted characteristics are derived from the predicted image. In some embodiments, the predicted characteristic comprises predicted geometry, and the predicted geometry comprises an etch contour, for example. In some embodiments, a predicted characteristic comprises a predicted critical dimension (CD) for the second pattern layout. In some embodiments, the predicted characteristic comprises a plurality of critical dimensions predicted by the simulation model for the one or more selected portions and the one or more moved portions in the second pattern layout.

At an operation 310, the stability of the simulation model is determined based on the one or more predicted characteristics. Determining the stability comprises determining one or more predicted characteristics associated with the one or more selected portions and the one or more moved portions with the simulation model. In some embodiments, determining the stability of the simulation model based on the one or more predicted characteristics and/or other information comprises a grid dependency (GD) check of the simulation model.

In some embodiments, operation 308 comprises applying the simulation model only once on the second pattern layout to produce all the characteristics (e.g., CDs) of the selected portions with varying rotations and/or shifts (e.g., the moved portions), and operation 310 comprises using the characteristics (e.g., the CDs) to derive a grid dependency metric, for example. Determining the stability of the simulation model may be based on the range of the plurality of CDs, as one example. Other examples, include the range/variation/standard deviation of any characteristic, such as CD, edge placement, edge placement error, etc.; contour to contour differences; the range of model signals at evaluation positions; etc.

In some embodiments, operation 310 comprises providing the determined simulation model stability (e.g., a grid dependency metric), the predicted characteristics, and/or other information for various downstream applications. In some embodiments, operation 310 includes providing this information for simulation model adjustments, pattern and/or process adjustments, and/or for other reasons. Providing may include electronically sending, uploading, and/or otherwise inputting this information to a computing device. In some embodiments, the computing device may be integrally programmed with the instructions that cause others of operations 302-310 (e.g., such that no “providing” is required, and instead data simply flows directly to the computing device).

For example, the determined simulation model stability, the predicted characteristics, and/or other information may be provided to tune and/or otherwise calibrate the simulation model described herein and/or one or more other machine learning simulation models. A machine learning simulation model may be associated with optical proximity correction (OPC), hotspot or defect prediction, and/or source mask optimization (SMO) for a semiconductor lithography process, and/or other operations.

Adjustments to a semiconductor manufacturing process may be made based on the predicted characteristics, output from a simulation model described above, and/or other information. Adjustments may including changing one or more semiconductor manufacturing process parameters, for example. Adjustments may include pattern parameter changes (e.g., sizes, locations, and/or other design variables), and/or any adjustable parameter such as an adjustable parameter of the etching system, the source, the patterning device, the projection optics, dose, focus, etc. Parameters may be automatically or otherwise electronically adjusted by a processor (e.g., a computer controller), modulated manually by a user, or adjusted in other ways. In some embodiments, parameter adjustments may be determined (e.g., an amount a given parameter should be changed), and the parameters may be adjusted from prior parameter set points to new parameter set points, for example.

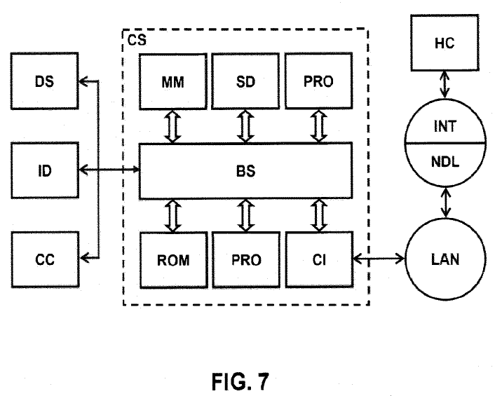

FIG. 7 is a diagram of an example computer system CS that may be used for one or more of the operations described herein. Computer system CS includes a bus BS or other communication mechanism for communicating information, and a processor PRO (or multiple processors) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

In some embodiments, portions of one or more methods described herein may be performed by computer system CS in response to processor PRO executing one or more sequences of one or more instructions contained in main memory MM. Such instructions may be read into main memory MM from another computer-readable medium, such as storage device SD. Execution of the sequences of instructions included in main memory MM causes processor PRO to perform the process steps (operations) described herein. One or more processors in a multi-processing arrangement may also be employed to execute the sequences of instructions contained in main memory MM. In some embodiments, hard-wired circuitry may be used in place of or in combination with software instructions. Thus, the description herein is not limited to any specific combination of hardware circuitry and software.

The term “computer-readable medium” and/or “machine readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the operations described herein. Transitory computer-readable media can include a carrier wave or other propagating electromagnetic signal, for example.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic, or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) may use electrical, electromagnetic, or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN, and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

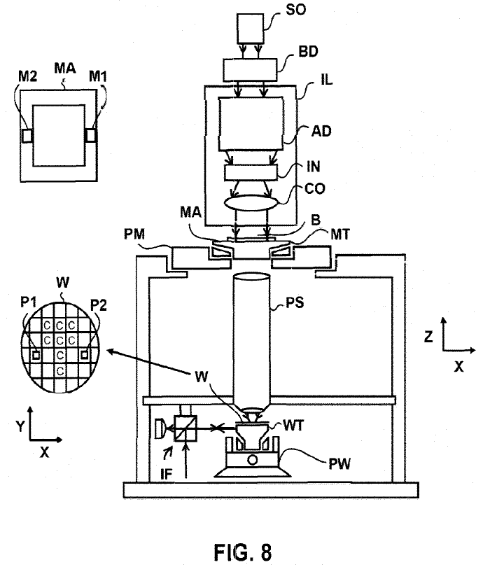

FIG. 8 is a schematic diagram of a lithographic projection apparatus, according to an embodiment. The lithographic projection apparatus can include an illumination system IL, a first object table MT, a second object table WT, and a projection system PS. Illumination system IL, can condition a beam B of radiation. In this example, the illumination system also comprises a radiation source SO. First object table (e.g., a patterning device table) MT can be provided with a patterning device holder to hold a patterning device MA (e.g., a reticle), and connected to a first positioner to accurately position the patterning device with respect to item PS. Second object table (e.g., a substrate table) WT can be provided with a substrate holder to hold a substrate W (e.g., a resist-coated silicon wafer), and connected to a second positioner to accurately position the substrate with respect to item PS. Projection system (e.g., which includes a lens) PS (e.g., a refractive, catoptric or catadioptric optical system) can image an irradiated portion of the patterning device MA onto a target portion C (e.g., comprising one or more dies) of the substrate W. Patterning device MA and substrate W may be aligned using patterning device alignment marks M1, M2 and substrate alignment marks P1, P2, for example.

As depicted, the apparatus can be of a transmissive type (i.e., has a transmissive patterning device). However, in general, it may also be of a reflective type, for example (with a reflective patterning device). The apparatus may employ a different kind of patterning device for a classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning means, such as a beam expander, or beam delivery system BD (comprising directing mirrors, the beam expander, etc.). for example. The illuminator IL may comprise adjusting means AD for setting the outer and/or inner radial extent (commonly referred to as σ-outer and σ-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

In some embodiments, source SO may be within the housing of the lithographic projection apparatus (as is often the case when source SO is a mercury lamp, for example), but that it may also be remote from the lithographic projection apparatus. The radiation beam that it produces may be led into the apparatus (e.g., with the aid of suitable directing mirrors), for example. This latter scenario can be the case when source SO is an excimer laser (e.g., based on KrF, ArF or F2 lasing), for example.

The beam B can subsequently intercept patterning device MA, which is held on a patterning device table MT. Having traversed patterning device MA, the beam B can pass through the lens PL, which focuses beam B onto target portion C of substrate W. With the aid of the second positioning means (and interferometric measuring means IF), the substrate table WT can be moved accurately, e.g. to position different target portions C in the path of beam B. Similarly, the first positioning means can be used to accurately position patterning device MA with respect to the path of beam B, e.g., after mechanical retrieval of the patterning device MA from a patterning device library, or during a scan. In general, movement of the object tables MT, WT can be realized with the aid of a long-stroke module (coarse positioning) and a short-stroke module (fine positioning). However, in the case of a stepper (as opposed to a step-and-scan tool), patterning device table MT may be connected to a short stroke actuator, or may be fixed.

The depicted tool can be used in two different modes, step mode and scan mode. In step mode, patterning device table MT is kept essentially stationary, and an entire patterning device image is projected in one operation (i.e., a single “flash”) onto a target portion C. Substrate table WT can be shifted in the x and/or y directions so that a different target portion C can be irradiated by beam B. In scan mode, essentially the same scenario applies, except that a given target portion C is not exposed in a single “flash.” Instead, patterning device table MT is movable in a given direction (e.g., the “scan direction”, or the “y” direction) with a speed v, so that projection beam B is caused to scan over a patterning device image. Concurrently, substrate table WT is simultaneously moved in the same or opposite direction at a speed V=Mv, in which M is the magnification of the lens (typically, M=¼ or ⅕). In this manner, a relatively large target portion C can be exposed, without having to compromise on resolution.

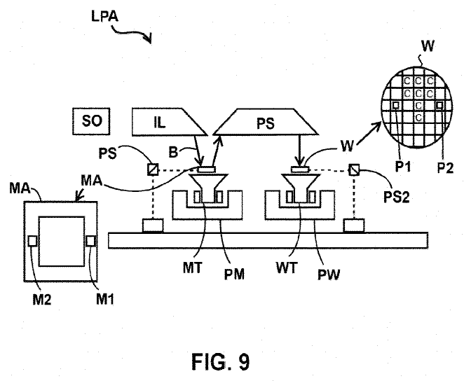

FIG. 9 is a schematic diagram of another lithographic projection apparatus (LPA) that may be used for, and/or facilitating one or more of the operations described herein. LPA can include source collector module SO, illumination system (illuminator) IL configured to condition a radiation beam B (e.g. EUV radiation), support structure MT, substrate table WT, and projection system PS. Support structure (e.g. a patterning device table) MT can be constructed to support a patterning device (e.g. a mask or a reticle) MA and connected to a first positioner PM configured to accurately position the patterning device. Substrate table (e.g. a wafer table) WT can be constructed to hold a substrate (e.g. a resist coated wafer) W and connected to a second positioner PW configured to accurately position the substrate. Projection system (e.g. a reflective projection system) PS can be configured to project a pattern imparted to the radiation beam B by patterning device MA onto a target portion C (e.g. comprising one or more dies) of the substrate W.

As shown in this example, LPA can be of a reflective type (e.g. employing a reflective patterning device). It is to be noted that because most materials are absorptive within the EUV wavelength range, the patterning device may have multilayer reflectors comprising, for example, a multi-stack of molybdenum and silicon. In one example, the multi-stack reflector has a 40 layer pairs of molybdenum and silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Illuminator IL can receive an extreme ultra violet radiation beam from source collector module SO. Methods to produce EUV radiation include, but are not necessarily limited to, converting a material into a plasma state that has at least one element, e.g., xenon, lithium, or tin, with one or more emission lines in the EUV range. In one such method, often termed laser produced plasma (“LPP”), the plasma can be produced by irradiating a fuel, such as a droplet, stream or cluster of material having the line-emitting element, with a laser beam. Source collector module SO may be part of an EUV radiation system including a laser (not shown in FIG. 9), for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation. In this example, the laser may not be considered to form part of the lithographic apparatus and the radiation beam can be passed from the laser to the source collector module with the aid of a beam delivery system comprising, for example, suitable directing mirrors and/or a beam expander. In other examples, the source may be an integral part of the source collector module, for example when the source is a discharge produced plasma EUV generator, often termed a DPP source.

Illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B can be incident on the patterning device (e.g., mask) MA, which is held on the support structure (e.g., patterning device table) MT, and is patterned by the patterning device. After being reflected from the patterning device (e.g. mask) MA, the radiation beam B passes through the projection system PS, which focuses the beam onto a target portion C of the substrate W. With the aid of the second positioner PW and position sensor PS2 (e.g. an interferometric device, linear encoder, or capacitive sensor), the substrate table WT can be moved accurately (e.g. to position different target portions C in the path of radiation beam B). Similarly, the first positioner PM and another position sensor PS1 can be used to accurately position the patterning device (e.g. mask) MA with respect to the path of the radiation beam B. Patterning device (e.g. mask) MA and substrate W may be aligned using patterning device alignment marks M1, M2 and substrate alignment marks P1, P2.

The depicted apparatus LPA could be used in at least one of the following modes, step mode, scan mode, and stationary mode. In step mode, the support structure (e.g. patterning device table) MT and the substrate table WT are kept essentially stationary, while an entire pattern imparted to the radiation beam is projected onto a target portion C at one time (e.g., a single static exposure). The substrate table WT is then shifted in the X and/or Y direction so that a different target portion C can be exposed. In scan mode, the support structure (e.g. patterning device table) MT and the substrate table WT are scanned synchronously while a pattern imparted to the radiation beam is projected onto target portion C (i.e. a single dynamic exposure). The velocity and direction of substrate table WT relative to the support structure (e.g. patterning device table) MT may be determined by the (de)magnification and image reversal characteristics of the projection system PS. In stationary mode, the support structure (e.g. patterning device table) MT is kept essentially stationary holding a programmable patterning device, and substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

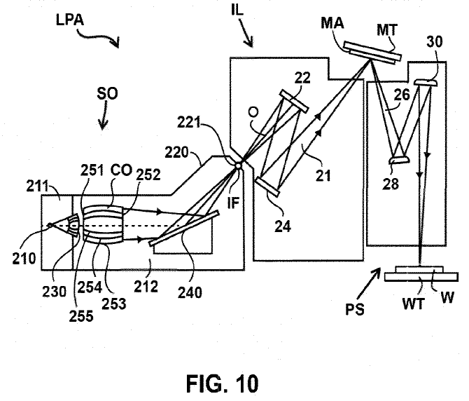

FIG. 10 is a detailed view of the lithographic projection apparatus shown in FIG. 9. As shown in FIG. 10, the LPA can include the source collector module SO, the illumination system IL, and the projection system PS. The source collector module SO is configured such that a vacuum environment can be maintained in an enclosing structure 220 of the source collector module SO. An EUV radiation emitting plasma 210 may be formed by a discharge produced plasma source. EUV radiation may be produced by a gas or vapor, for example Xe gas, Li vapor or Sn vapor in which the hot plasma 210 is created to emit radiation in the EUV range of the electromagnetic spectrum. The hot plasma 210 is created by, for example, an electrical discharge causing at least partially ionized plasma. Partial pressures of, for example, 10 Pa of Xe, Li, Sn vapor or any other suitable gas or vapor may be required for efficient generation of the radiation. In some embodiments, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contamination trap 230 may also include a gas barrier or a combination of a gas barrier and a channel structure. The contaminant trap or contaminant barrier trap 230 (described below) also includes a channel structure. The collector chamber 211 may include a radiation collector CO which may be a grazing incidence collector. Radiation collector CO has an upstream radiation collector side 251 and a downstream radiation collector side 252. Radiation that traverses collector CO can be reflected off a grating spectral filter 240 to be focused on a virtual source point IF along the optical axis indicated by the line “O”. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

Subsequently, the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the radiation beam 21 at the patterning device MA, held by the support structure MT, a patterned beam 26 is formed and the patterned beam 26 is imaged by the projection system PS via reflective elements 28, 30 onto a substrate W held by the substrate table WT. More elements than shown may generally be present in illumination optics unit IL and projection system PS. The grating spectral filter 240 may optionally be present, depending upon the type of lithographic apparatus, for example. Further, there may be more mirrors present than those shown in the figures, for example there may be 1-6 additional reflective elements present in the projection system PS than shown in FIG. 10.

Collector optic CO, as illustrated in FIG. 10, is depicted as a nested collector with grazing incidence reflectors 253, 254 and 255, just as an example of a collector (or collector mirror). The grazing incidence reflectors 253, 254 and 255 are disposed axially symmetric around the optical axis O and a collector optic CO of this type may be used in combination with a discharge produced plasma source, often called a DPP source.

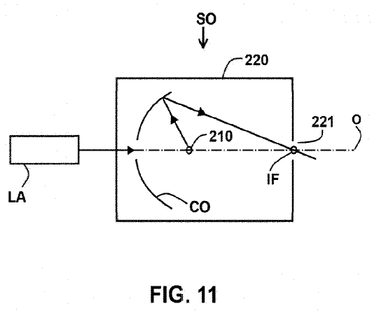

FIG. 11 is a detailed view of source collector module SO of the lithographic projection apparatus LPA (shown in previous figures). Source collector module SO may be part of an LPA radiation system. A laser LA can be arranged to deposit laser energy into a fuel, such as xenon (Xe), tin (Sn) or lithium (Li), creating the highly ionized plasma 210 with electron temperatures of several 10″s of eV. The energetic radiation generated during de-excitation and recombination of these ions is emitted from the plasma, collected by a near normal incidence collector optic CO and focused onto the opening 221 in the enclosing structure 220.

The concepts disclosed herein may simulate or mathematically model any generic imaging, etching, polishing, inspection, etc. system for sub wavelength features, and may be useful with emerging imaging technologies capable of producing increasingly shorter wavelengths. Emerging technologies include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-50 nm by using a synchrotron or by hitting a material (either solid or a plasma) with high energy electrons in order to produce photons within this range.

Embodiments of the present disclosure can be further described by the following clauses.

1. A non-transitory computer readable medium having instructions thereon, the instructions when executed by one or more processors causing the one or more processors to perform a method comprising:
extracting one or more selected portions of a first pattern layout, the first pattern layout overlaid on a grid;
moving the one or more selected portions relative to the grid to form one or more moved portions;
generating a second pattern layout comprising the one or more selected portions and the one or more moved portions; and
providing the second pattern layout to a simulation model to determine one or more predicted characteristics for the one or more selected portions and the one or more moved portions.

2. The medium of clause 1, wherein the method further comprises:
determining a stability of the simulation model based on the one or more predicted characteristics.

3. The medium of clause 2, wherein the determining the stability comprises determining one or more predicted characteristics associated with the one or more selected portions and the one or more moved portions with the simulation model based on the second pattern layout.

4. The medium of clause 2 or 3, wherein determining the stability of the simulation model based on the one or more predicted characteristics comprises a grid dependency (GD) check of the simulation model.

5. The medium of any of clauses 1-4, wherein a predicted characteristic comprises a predicted image and/or a predicted geometry for the second pattern layout.

6. The medium of clause 5, wherein determining the one or more predicted characteristics comprises generating the predicted image, the predicted image comprises a resist image, and the one or more predicted characteristics are derived from the predicted image.

7. The medium of clause 5, wherein the predicted characteristic comprises the predicted geometry, and the predicted geometry comprises an etch contour.

8. The medium of any of clauses 1-7, wherein a predicted characteristic comprises a predicted critical dimension (CD) for the second pattern layout.

9. The medium of clause 8, wherein the predicted characteristic comprises a plurality of critical dimensions predicted by the simulation model for the one or more selected portions and the one or more moved portions in the second pattern layout, and wherein determining a stability of the simulation model is based on a range of the plurality of critical dimensions.

10. The medium of any of clauses 1-9, wherein moving the one or more selected portions relative to the grid comprises rotating and/or shifting the one or more selected portions relative to the grid.

11. The medium of any of clauses 1-10, wherein a size of the one or more selected portions is determined based on simulation model erosion.

12. The medium of any of clauses 1-11, wherein a size of the one or more selected portions is minimized based on simulation model erosion.

13. The medium of any of clauses 1-12, wherein a selected portion has a dimension of about 1 to about 20 micrometers.

14. The medium of any of clauses 1-13, wherein the pattern layout comprises a design layout for a semiconductor manufacturing process.

15. The medium of clause 14, wherein the simulation model comprises a lithography simulation model.

16. The medium of clause 14 or 15, wherein a selected portion has a first dimension for an extreme ultraviolet (EUV) semiconductor manufacturing process, or a second, larger dimension, for a deep ultraviolet (DUV) semiconductor manufacturing process.

17. The medium of any of clauses 14-16, wherein the simulation model is configured for an optical proximity correction (OPC) process, and wherein the one or more selected portions have a smaller dimensional size than portions used by the simulation model in the OPC process.

18. The medium of any of clauses 1-17, wherein the instructions further cause the one or more processors to electronically access the first pattern layout, the first pattern layout comprising a graphic design system (.GDS) or OASIS file.

19. A method of determining a stability of a simulation model, the method comprising:
extracting one or more selected portions of a first pattern layout, the first pattern layout overlaid on a grid;
moving the one or more selected portions relative to the grid to form one or more moved portions;
generating a second pattern layout comprising the one or more selected portions and the one or more moved portions; and
providing the second pattern layout to a simulation model to determine one or more predicted characteristics for the one or more selected portions and the one or more moved portions.

20. The method of clause 19, further comprising:
determining a stability of the simulation model based on the one or more predicted characteristics.

21. The method of clause 20, wherein the determining the stability comprises determining one or more predicted characteristics associated with the one or more selected portions and the one or more moved portions with the simulation model based on the second pattern layout.

22. The method of clause 20 or 21, wherein determining the stability of the simulation model based on the one or more predicted characteristics comprises a grid dependency (GD) check of the simulation model.

23. The method of any of clauses 19-22, wherein a predicted characteristic comprises a predicted image and/or a predicted geometry for the second pattern layout.

24. The method of clause 23, wherein determining the one or more predicted characteristics comprises generating the predicted image, the predicted image comprises a resist image, and the one or more predicted characteristics are derived from the predicted image.

25. The method of clause 23, wherein the predicted characteristic comprises the predicted geometry, and the predicted geometry comprises an etch contour.

26. The method of any of clauses 19-25, wherein a predicted characteristic comprises a predicted critical dimension (CD) for the second pattern layout.

27. The method of clause 26, wherein the predicted characteristic comprises a plurality of critical dimensions predicted by the simulation model for the one or more selected portions and the one or more moved portions in the second pattern layout, and wherein determining a stability of the simulation model is based on a range of the plurality of critical dimensions.

28. The method of any of clauses 19-27, wherein moving the one or more selected portions relative to the grid comprises rotating and/or shifting the one or more selected portions relative to the grid.

29. The method of any of clauses 19-28, wherein a size of the one or more selected portions is determined based on simulation model erosion.

30. The method of any of clauses 19-29, wherein a size of the one or more selected portions is minimized based on simulation model erosion.

31. The method of any of clauses 19-30, wherein a selected portion has a dimension of about 1 to about 20 micrometers.

32. The method of any of clauses 19-31, wherein the pattern layout comprises a design layout for a semiconductor manufacturing process.

33. The method of clause 32, wherein the simulation model comprises a lithography simulation model.

34. The method of clauses 32 or 33, wherein a selected portion has a first dimension for an extreme ultraviolet (EUV) semiconductor manufacturing process, or a second, larger dimension, for a deep ultraviolet (DUV) semiconductor manufacturing process.

35. The method of any of clauses 32-34, wherein the simulation model is configured for an optical proximity correction (OPC) process, and wherein the one or more selected portions have a smaller dimensional size than portions used by the simulation model in the OPC process.

36. The method of any of clauses 19-35, further comprising causing one or more processors to electronically access the first pattern layout, the first pattern layout comprising a graphic design system (.GDS) or OASIS file.

37. A non-transitory computer readable medium having instructions thereon, the instructions when executed by one or more processors causing the one or more processors to perform the method of any of clauses 19-36.

38. A system comprising one or more processors and a computer readable medium having instructions thereon, the instructions, when executed by one or more processors, causing the one or more processors to perform the method of any of clauses 19-36.

39. A system comprising one or more processors and a computer readable medium having instructions thereon, the instructions, when executed by one or more processors, causing the one or more processors to perform operations comprising:
extracting one or more selected portions of a first pattern layout, the first pattern layout overlaid on a grid;
moving the one or more selected portions relative to the grid to form one or more moved portions;
generating a second pattern layout comprising the one or more selected portions and the one or more moved portions; and
providing the second pattern layout to a simulation model to determine one or more predicted characteristics for the one or more selected portions and the one or more moved portions.

40. The system of clause 39, wherein the operations further comprise:
determining a stability of the simulation model based on the one or more predicted characteristics.

41. The system of clause 40, wherein the determining the stability comprises determining one or more predicted characteristics associated with the one or more selected portions and the one or more moved portions with the simulation model based on the second pattern layout.

42. The system of clause 40 or 41, wherein determining the stability of the simulation model based on the one or more predicted characteristics comprises a grid dependency (GD) check of the simulation model.

43. The system of any of clauses 39-42, wherein a predicted characteristic comprises a predicted image and/or a predicted geometry for the second pattern layout.

44. The system of clause 43, wherein determining the one or more predicted characteristics comprises generating the predicted image, the predicted image comprises a resist image, and the one or more predicted characteristics are derived from the predicted image.

45. The system of clause 43, wherein the predicted characteristic comprises the predicted geometry, and the predicted geometry comprises an etch contour.

46. The system of any of clauses 39-45, wherein a predicted characteristic comprises a predicted critical dimension (CD) for the second pattern layout.

47. The system of clause 46, wherein the predicted characteristic comprises a plurality of critical dimensions predicted by the simulation model for the one or more selected portions and the one or more moved portions in the second pattern layout, and wherein determining a stability of the simulation model is based on a range of the plurality of critical dimensions.

48. The system of any of clauses 37-45, wherein moving the one or more selected portions relative to the grid comprises rotating and/or shifting the one or more selected portions relative to the grid.

47. The system of any of clauses 39-48, wherein a size of the one or more selected portions is determined based on simulation model erosion.

50. The system of any of clauses 39-49, wherein a size of the one or more selected portions is minimized based on simulation model erosion.

51. The system of any of clauses 39-50, wherein a selected portion has a dimension of about 1 to about 20 micrometers.

52. The system of any of clauses 39-51, wherein the pattern layout comprises a design layout for a semiconductor manufacturing process.

53. The system of clause 52, wherein the simulation model comprises a lithography simulation model.

54. The system of clause 52 or 53, wherein a selected portion has a first dimension for an extreme ultraviolet (EUV) semiconductor manufacturing process, or a second, larger dimension, for a deep ultraviolet (DUV) semiconductor manufacturing process.

55. The system of any of clauses 52-54, wherein the simulation model is configured for an optical proximity correction (OPC) process, and wherein the one or more selected portions have a smaller dimensional size than portions used by the simulation model in the OPC process.

56. The system of any of clauses 39-55, wherein the instructions further cause the one or more processors to electronically access the first pattern layout, the first pattern layout comprising a graphic design system (.GDS) or OASIS file.

57. A non-transitory computer readable medium having instructions thereon, the instructions when executed by a computer, causing the computer to perform a grid dependency check for a simulation model, the grid dependency check performed faster and with less required data compared to prior grid dependency checks because certain portions of a first design layout are cropped to a smaller size than in the prior grid dependency checks, and used to generate a second design layout, so that a modeling operation need only run a single time instead of multiple times as in the prior grid dependency checks, the instructions causing the computer to perform operations comprising:
electronically accessing a first design layout for a semiconductor manufacturing process, the first design layout overlaid on a grid, the first design layout comprising a first graphic design system (.GDS) or OASIS file;
extracting one or more selected portions of first design layout from the .GDS or OASIS file;
rotating and/or shifting the one or more selected portions relative to the grid to form one or more moved portions;
generating a second design layout comprising the one or more selected portions and the one or more moved portions, the second design layout comprising a second .GDS or OASIS file;
using a lithography simulation model to determine one or more predicted results for the one or more selected portions and the one or more moved portions based on the second design layout; and
perform the grid dependency check for the simulation model based on the one or more predicted results, wherein the grid dependency of the simulation model is indicated by variation in the one or more predicted results caused by positions of the one or more selected portions and the one or more moved portions in the second design layout relative to the grid.

58. The medium of clause 57, wherein a predicted result comprises a predicted resist image, a predicted etch contour, and/or a predicted critical dimension (CD) for the second design layout.

59. The medium of clause 57, wherein the predicted result comprises a plurality of critical dimensions from different ones of the one or more selected portions and the one or more moved portions in the second design layout, and wherein the grid dependency check of the simulation model is based on a range of the plurality of critical dimensions.

60. The medium of clause 57, wherein a size of the one or more selected portions is minimized based on simulation model erosion.

61. The medium of clause 55, wherein the simulation model is configured for a typical optical proximity correction (OPC) process, and wherein the one or more selected portions have a smaller dimensional size than portions used by the simulation model in the typical OPC process.

While the concepts disclosed herein may be used for manufacturing with a substrate such as a silicon wafer, it shall be understood that the disclosed concepts may be used with any type of manufacturing system (e.g., those used for manufacturing on substrates other than silicon wafers).

In addition, the combination and sub-combinations of disclosed elements may comprise separate embodiments. For example, one or more of the operations described above may be included in separate embodiments, or they may be included together in the same embodiment.

The descriptions above are intended to be illustrative, not limiting. Thus, it will be apparent to one skilled in the art that modifications may be made as described without departing from the scope of the claims set out below.

1. A non-transitory computer readable medium having instructions thereon or therein, the instructions, when executed by one or more processors, configured to cause the one or more processors to at least:
extract one or more selected portions of a first pattern layout, the first pattern layout overlaid on a grid;
move the one or more selected portions relative to the grid to form one or more moved portions;
generate a second pattern layout comprising the one or more selected portions and the one or more moved portions; and
provide the second pattern layout to a simulation model to determine one or more predicted characteristics for the one or more selected portions and the one or more moved portions.

2. The medium of claim 1, wherein the instructions are further configured to cause the one or more processors to determine a stability of the simulation model based on the one or more predicted characteristics.

3. The medium of claim 2, wherein the instructions configured to cause the one or processors to determine the stability are further configured to cause the one or more processors to determine one or more predicted characteristics associated with the one or more selected portions and the one or more moved portions with the simulation model based on the second pattern layout.

4. The medium of claim 2, wherein the instructions configured to cause the one or processors to determine the stability are further configured to cause the one or more processors to perform a grid dependency (GD) check of the simulation model.

5. The medium of claim 1, wherein a predicted characteristic comprises a predicted image and/or a predicted geometry for the second pattern layout.

6. The medium of claim 5, wherein the predicted characteristic comprises the predicted image and wherein the instructions configured to cause the one or processors to determine the one or more predicted characteristics are further configured to cause the one or more processors to generate the predicted image, the predicted image comprising a resist image, and the one or more predicted characteristics are derived from the predicted image.

7. The medium of claim 5, wherein the predicted characteristic comprises the predicted geometry, and the predicted geometry comprises an etch contour.

8. The medium of claim 1, wherein a predicted characteristic comprises a predicted critical dimension (CD) for the second pattern layout.

9. The medium of claim 8, wherein the predicted characteristic comprises a plurality of critical dimensions predicted by the simulation model for the one or more selected portions and the one or more moved portions in the second pattern layout, and wherein the instructions configured to cause the one or processors to determine the stability are further configured to cause the one or more processors to determine the stability based on a range of the plurality of critical dimensions.

10. The medium of claim 1, wherein the instructions configured to cause the one or processors to move the one or more selected portions relative to the grid are further configured to cause the one or more processors to rotate and/or shift the one or more selected portions relative to the grid.

11. The medium of claim 1, wherein a size of the one or more selected portions is determined based on simulation model erosion.

12. The medium of claim 1, wherein the pattern layout comprises a design layout for a semiconductor manufacturing process, and wherein the simulation model comprises a lithography simulation model.

13. The medium of claim 12, wherein a selected portion has a first dimension for an extreme ultraviolet (EUV) semiconductor manufacturing process, or a second, larger dimension, for a deep ultraviolet (DUV) semiconductor manufacturing process.

14. The medium of claim 1, wherein the simulation model is configured for an optical proximity correction (OPC) process, and wherein the one or more selected portions have a smaller dimensional size than portions used by the simulation model in the OPC process.

15. The medium of claim 1, wherein the instructions further cause the one or more processors to electronically access the first pattern layout, the first pattern layout comprising a graphic design system (.GDS) or OASIS file.

16. A non-transitory computer readable medium having instructions thereon or therein, the instructions, when executed by a computer system, configured to cause the computer system to at least:
electronically access a first design layout for a semiconductor manufacturing process, the first design layout overlaid on a grid;
extract one or more selected portions of the first design layout;
rotate and/or shift the one or more selected portions relative to the grid to form one or more moved portions;
generate a second design layout comprising the one or more selected portions and the one or more moved portions;
use a lithography simulation model to determine one or more predicted results for the one or more selected portions and the one or more moved portions based on the second design layout; and
perform a grid dependency check for the simulation model based on the one or more predicted results, wherein the grid dependency of the simulation model is indicated by variation in the one or more predicted results caused by positions of the one or more selected portions and the one or more moved portions in the second design layout relative to the grid.

17. The medium of claim 16, wherein a predicted result comprises a predicted resist image, a predicted etch contour, and/or a predicted critical dimension (CD) for the second design layout.

18. The medium of claim 16, wherein a predicted result comprises a plurality of critical dimensions from different ones of the one or more selected portions and the one or more moved portions in the second design layout, and wherein the grid dependency check of the simulation model is based on a range of the plurality of critical dimensions.

19. The medium of claim 16, wherein a size of the one or more selected portions is minimized based on simulation model erosion.

20. The medium of claim 16, wherein the simulation model is configured for an optical proximity correction (OPC) process, and wherein the one or more selected portions have a smaller dimensional size than portions used by the simulation model in the OPC process.
